(19) United States
(12) Patent Application Publication
(10) Pub. No.: US 2013/0048994 A1
(43) Pub. Date: Feb. 28, 2013

(54) LOW-RESISTANCE CONDUCTIVE LINE, THIN FILM TRANSISTOR, THIN FILM TRANSISTOR PANEL, AND METHOD FOR MANUFACTURING THE SAME

(71) Applicants: Shin-Il CHOI, Hwaseong-si (KR); Yong-Hwan RYU, Yongin-si (KR); Hong-Sick PARK, Suwon-si (KR); Seung-Ha CHOI, Suwon-si (KR)

(72) Inventors: Shin-Il CHOI, Hwaseong-si (KR); Yong-Hwan RYU, Yongin-si (KR); Hong-Sick PARK, Suwon-si (KR); Seung-Ha CHOI, Suwon-si (KR)

(73) Assignee: Samsung Display Co., Ltd., Yongin-si (KR)

(21) Appl. No.: 13/590,845

(22) Filed: Aug. 21, 2012

(30) Foreign Application Priority Data
Aug. 23, 2011 (KR) 10-2011-0083971

(51) Int. Cl. H01L 29/786; H01L 23/48; H01L 21/336

(52) U.S. Cl. 257/59; 438/34; 257/57; 257/741; 257/E29.273; 257/E21.409; 257/E23.01

(57) ABSTRACT

A Thin Film Transistor (TFT) has a capping layer disposed on the surface of at least one of source and drain electrodes on a substrate, a protective film disposed on the capping layer, and a conductive layer electrically connected to the capping layer via a contact hole formed in the protective layer film.

### CROSS-REFERENCE TO RELATED APPLICATION

This application claims priority from and the benefit of Korean Patent Application No. 10-2011-0083971 filed in the Korean Intellectual Property Office on Aug. 23, 2011, which is incorporated herein by reference for all purposes as if fully set forth herein.

### BACKGROUND OF THE INVENTION

1. Field of the Invention

The present invention relates to a low-resistance conductive line, a Thin Film Transistor (TFT), a TFT panel, and a method for manufacturing the same.

2. Discussion of the Background

Recently, electronic devices such as a display device and a semiconductor device use low-resistance conductive lines. The semiconductor device uses copper (Cu) for its low-resistance conductive lines or electrodes, for miniaturization and high-speed operation caused by the high integration. Even in the field of the display device, such as a liquid crystal display device and an organic light-emitting display, low-resistance conductive lines are required due to an increase in resolution and display area of the display device, and to the high integration of sensors and driver circuitry, which can be integrated in the display device. Therefore, gate lines, data lines, and TFT's gate, drain, and source electrodes, used in the display device, are all formed of copper (Cu) or copper alloy. A protective layer may be formed on the conductive layer which is formed of copper or copper alloy.

### SUMMARY OF THE INVENTION

Additional features of the invention will be set forth in the description which follows, and in part will be apparent from the description, or may be learned by practice of the invention.

An exemplary embodiment of the present invention provides a low-resistance conductive line, a Thin Film Transistor (TFT), a TFT panel, and a method for manufacturing the same, capable of preventing an increase in contact resistance of copper or copper alloy.

In accordance with one aspect of the present invention, a Thin Film Transistor (TFT) panel is provided. The TFT panel includes a substrate; a source electrode and a drain electrode disposed on the substrate and spaced apart from each other; a capping layer disposed on top surfaces and sidewalls of the source electrode and the drain electrode; a protective film disposed on the source electrode and the drain electrode; a contact hole formed in the protective film and exposing the capping layer; and a pixel electrode electrically connected to the exposed portion of the capping layer via the contact hole.

In accordance with another aspect of the present invention, a method for manufacturing a Thin Film Transistor (TFT) panel is provided. The method includes forming a source electrode and a drain electrode on a substrate; forming a capping layer by performing plasma treatment on the source and drain electrodes in an oxygen atmosphere; forming a protective film on the source electrode, the drain electrode, and the capping layer; forming a contact hole in the protective film to expose the capping layer; and forming a pixel electrode electrically connected to the capping layer via the contact hole.

In accordance with still another aspect of the present invention, an electronic device is provided. The electronic device includes a substrate; a lower conductive layer disposed on the substrate and comprising copper; a capping layer disposed on a top and a sidewall of the lower conductive layer; an interlayer insulating film disposed on the capping layer; a contact hole formed in the interlayer insulating film; and an upper conductive layer electrically connected to the capping layer via the contact hole.

In accordance with yet another aspect of the present invention, a Thin Film Transistor (TFT) is provided. The TFT includes a substrate; a gate electrode, a source electrode and a drain electrode disposed on the substrate; an oxide semiconductor layer interposed between the gate electrode and the source and drain electrodes, wherein at least one of the source and drain electrodes comprises copper; a capping layer disposed on a top and a sidewall of any one of the source and drain electrodes, which comprises copper; and a protective film disposed on the capping layer.

It is to be understood that both the forgoing general description and the following detailed description are exemplary and explanatory and are intended to provide further explanation of the invention as claimed.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a partial cross-sectional view of an electronic device according to an embodiment of the present invention;

FIG. 2 is a cross-sectional view of a TFT with a low-resistance electrode according to an embodiment of the present invention;

FIGS. 3A to 3H are cross sectional views to illustrate a method for manufacturing the TFT shown in FIG. 2;

FIG. 4 is a layout of a TFT panel according to an embodiment of the present invention;

FIG. 5 is a cross-sectional view taken along the line IV-IV′ of the TFT panel shown in FIG. 4; and

FIG. 6 is a cross-sectional view of a TFT panel according to another embodiment of the present invention.

### DETAILED DESCRIPTION OF THE ILLUSTRATED EMBODIMENTS

The present invention will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art.

In the drawings, the thickness of layers, films, panels, regions, etc., may be exaggerated for clarity. It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. In contrast, It will be understood that when an element such as a layer, film, region, or substrate is referred to as being “beneath” another element, it can be directly beneath the other element or intervening elements may also be present. Meanwhile, when an element is referred to as being “directly beneath” another element, there are no intervening elements present.

As described above, a protective layer may be formed on a conductive layer formed of copper or copper alloy. It was found by the inventors that the surface of the conductive layer was discolored during the etching process of the formed protective layer. It is presumed that the discolored layer is generated because a metal oxide film or a metal sulfide film is formed as included oxygen or sulfur reacts to copper on the surface of the conductive layer during the etching process of the protective layer. The discolored layer on the surface of the conductive layer may cause an increase in contact resistance for connection, making it difficult to achieve low-resistance connection.

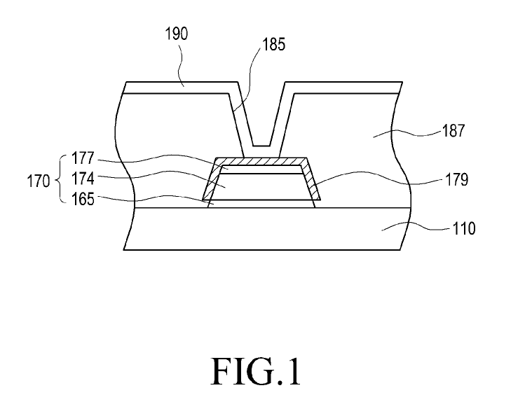

FIG. 1 is a partial cross-sectional view of an electronic device according to an embodiment of the present invention.

As shown in FIG. 1, a lower conductive layer 170 may be disposed on a substrate 110. The substrate 110 may be a substrate of semiconductor such as monocrystalline or polycrystalline silicon, or may be a substrate of glass, sapphire or plastic. Although not illustrated, a lower film such as an insulating film, a semiconductor layer, or a conductive layer may be interposed between the substrate 110 and the lower conductive layer 170.

The lower conductive layer 170 may include a first conductive layer 165, a second conductive layer 174, and a third conductive layer 177. The first conductive layer 165 may include gallium zinc oxide (GaZnO), titanium (Ti), titanium alloy (such as TiN), molybdenum (Mo), copper (Cu), copper alloy (such as CuMn), or Cu-alloy nitride (such as CuMnN). The first conductive layer 165 may be formed to have a thickness of about 100 Å to about 600 Å. The first conductive layer 165 may improve interfacial properties between the second conductive layer 174 and the lower film. The first conductive layer 165 may prevent atoms of the second conductive layer 174 from diffusing into the lower film through the first conductive layer 165. The second conductive layer 174 may be formed on the first conductive layer 165. The second conductive layer 174 may include copper or copper alloy. The copper alloy may include copper, and manganese (Mn), magnesium (Mg), aluminum (Al), zinc (Zn), or tin (Sn) of about 0.1 atomic % to about 30 atomic %. In accordance with another embodiment, the copper alloy may include vanadium (V), titanium (Ti), zirconium (Zr), tantalum (Ta), chrome (Cr), molybdenum (Mo), cobalt (Co), niobium (Nb), or nickel (Ni). The second conductive layer 174 may be formed to have a thickness of about 1,000 Å to about 5,000 Å. The third conductive layer 177 may be disposed on the second conductive layer 174. The third conductive layer 177 may be formed to have a thickness of about 100 Å to about 1,000 Å. The third conductive layer 177 may be formed of Cu-alloy nitride, CuMn alloy, CuMnAl alloy, or CuMn nitride (CuMnN). The Cu-alloy nitride may include aluminum (Al), zinc (Zn), tin (Sn), vanadium (V), titanium (Ti), zirconium (Zr), tantalum (Ta), manganese (Mn), magnesium (Mg), chrome (Cr), molybdenum (Mo), cobalt (Co), niobium (Nb), or nickel (Ni). The third conductive layer 177 may prevent the second conductive layer 174 from being oxidized in a below-described process of forming an interlayer insulating film 187.

A capping layer 179 may be formed on the top and sidewalls of the lower conductive layer 170 including copper. Although the capping layer 179 is formed on the sidewalls of the first to third conductive layers 165, 174 and 177 in FIG. 1, if the first conductive layer 165 includes no copper but includes some other materials, for example, gallium zinc oxide (GaZnO), titanium alloy and molybdenum (Mo), the capping layer 179 may not be formed on the sidewalls of the first conductive layer 165. The capping layer 179 may prevent the third conductive layer 177 from forming a discolored layer through discoloring in the subsequent process, for example, in the below-described etching process of the interlayer insulating film 187. In the absence of the capping layer 179, a discolored layer may be formed as atoms of a metal such as copper included in the third conductive layer 177 react with oxygen or sulfur during the etching process of the interlayer insulating film 187, forming a metal oxide film or a metal sulfide film on the surface of the third conductive layer 177. The discolored layer may change a unique color of the conductive layer. For example, the discolored layer may be seen blue, red, or black because of a change in color of the conductive layer including copper, which generally has a yellowish color. The color of the discolored layer is subject to change depending on the surface roughness, illumination, or microscope. The discolored layer, which increases contact resistance between the third conductive layer 177 and a below-described upper conductive layer 190, may have a thickness of about 1 μm and increase the surface roughness of the third conductive layer 177. The increased surface roughness may cause disconnection of the upper conductive layer 190 when the upper conductive layer 190 is formed. The disconnection of the upper conductive layer 190 may significantly increase the contact resistance between the upper conductive layer 190 and the third conductive layer 177.

The capping layer 179 may have a thickness of about 20 Å to about 100 Å. The capping layer 179 may include a cuprous oxide (CuO) film. The film of cuprous oxide (CuO) may prevent the third conductive layer 177 from forming a discolored layer by further reacting to oxygen or sulfur during the subsequent process because it has a higher density compared to the discolored layer. The cuprous oxide (CuO) film may have less surface roughness compared to the discolored layer. The capping layer 179 may be formed by oxygen plasma treatment. The plasma treatment may be performed at a pressure of about 30 mTorr to about 200 mTorr, and at a power density of about 0.5 W/cm² or more. During the plasma treatment, oxygen may be used, and an inert gas such as argon or helium may be further used. The plasma treatment may be performed at room temperature for 10 seconds or more. In accordance with another embodiment, the plasma treatment may be performed at 150° C. or below.

The interlayer insulating film 187 may be formed on the capping layer 179 and the substrate 110. The interlayer insulating film 187 may have a thickness of about 300 Å to about 50,000 Å. The interlayer insulating film 187 may be made of silicon oxide (SiOx), silicon nitride (SiNx), or a combination thereof. In accordance with another embodiment, the interlayer insulating film 187 may be formed of an inorganic insulating material such as titanium oxide (TiO₂), alumina (Al₂O₃) or zirconia (ZrO₂), or an organic insulating material such as poly siloxane, phenyl siloxane, polyimide, silsesquioxane or silane.

A contact hole 185 may be formed in the interlayer insulating film 187 to expose the capping layer 179. The contact hole 185 may be formed by patterning the interlayer insulating film 187 using a photolithography process in which a photoresist film is used. In accordance with an embodiment, when including silicon oxide (SiOx), the interlayer insulating film 187 may be patterned by dry etching. The dry etching may be performed using an SF₆ gas at a pressure of about 15 mTorr and at a power of about 1,000 W. The SF₆ used in the etching process of the interlayer insulating film 187 and the sulfur (S) included in the photoresist film may form a metal sulfide film by reacting to the metal layer. The sulfur (S) may facilitate the oxidation of the metal layer. This reaction between the sulfur (S) and the lower conductive layer 170 may be reduced by the capping layer 179.

The upper conductive layer 190 may be formed on the interlayer insulating film 187, and formed on the sidewalls of the contact hole 185 and the exposed surface of the capping layer 179. The upper conductive layer 190 may be formed of a material such as silver (Ag), silver alloy, copper (Cu), copper alloy, chrome (Cr), chrome alloy, nickel (Ni), nickel alloy, tungsten (W), tungsten alloy, molybdenum (Mo), molybdenum alloy, titanium (Ti), titanium alloy, tantalum (Ta), tantalum alloy, aluminum (Al), aluminum alloy, and mixtures thereof. The upper conductive layer 190 may be made of transparent conductor, and it may have a single or multi-layer structure, such as a double-layer structure or triple-layer structure.

In accordance with an embodiment of the present invention, the capping layer 179 may prevent the lower conductive layer 170 from being discolored by reacting to the oxygen or sulfur in the subsequent process such as the etching process of the interlayer insulating film 187, because it has a higher density and a less surface roughness, compared with the discolored layer.

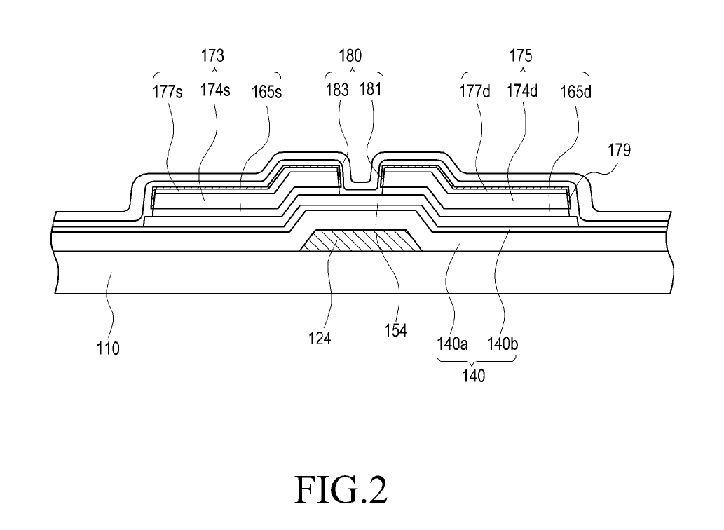

FIG. 2 is a cross-sectional view of a TFT with a low-resistance electrode according to an embodiment of the present invention.

As shown in FIG. 2, a gate electrode 124 may be disposed on a substrate 110. The substrate 110 may be a substrate of monocrystalline or polycrystalline silicon, or may be a substrate of glass or plastic.

The gate electrode 124 may be formed of a material such as silver (Ag), silver alloy, copper (Cu), copper alloy, chrome (Cr), chrome alloy, nickel (Ni), nickel alloy, tungsten (W), tungsten alloy, molybdenum (Mo), molybdenum alloy, titanium (Ti), titanium alloy, tantalum (Ta), tantalum alloy, aluminum (Al), aluminum alloy, and mixtures thereof. In accordance with an embodiment of the present invention, the gate electrode 124 may have a single or multi-layer structure. For example, the gate electrode 124 may have a double-layer structure including a first layer formed of titanium or titanium alloy and a second layer formed of copper or copper alloy. A thickness of the first layer may fall within the range of about 50 Å to about 1,000 Å, and a thickness of the second layer may fall within the range of about 1,000 Å to about 10,000 Å. In accordance with another embodiment, the double-layer structure may be Mo/Al, Ti/Al, Ta/Al, Ni/Al, TiNx/Al, Co/Al, CuMn/Cu, Ti/Cu, TiN/Cu, or TiOx/Cu. In accordance with further another embodiment, the gate electrode 124 may have a triple-layer structure. The triple-layer structure may be Mo/Al/Mo, Ti/Al/Ti, Co/Al/Co, Ti/Al/Ti, TiNx/Al/Ti, Ti/Cu/CuMn, TiMn/Cu/CuMn, CuMn/Cu/CuMn, Ti/Cu/Ti, TiNx/Cu/TiNx, or TiOx/Cu/TiOx.

A gate insulating film 140 may be formed on the gate electrode 124. The gate insulating film 140 may include a first gate insulating film 140a and a second gate insulating film 140b. The first gate insulating film 140a is in contact with the gate electrode 124, while the second gate insulating film 140b is in contact with a below-described semiconductor layer 154. The first gate insulating film 140a may be formed of silicon nitride (SiNx), while the second gate insulating film 140b may be formed of silicon oxide (SiOx). The first gate insulating film 140a may have a thickness of about 1,000 Å to about 5,000 Å. The second gate insulating film 140b may have a thickness of about 300 Å to about 2,000 Å. In accordance with another embodiment of the present invention, the gate insulating film 140 may include SiOxNy, SiOF, SiNF or SiONF.

The semiconductor layer 154 may be formed on the gate insulating film 140. The semiconductor layer 154 according to the present invention may be made of oxide semiconductor. The oxide semiconductor may include indium gallium zinc oxide (InGaZnO), or indium zinc tin oxide (InZnSnO). In accordance with another embodiment, the oxide semiconductor may be a compound having a formula expressed in A_{X}B_{X}O_{X} or A_{X}B_{X}C_{X}O_{X}, where A may be zinc (Zn) or cadmium (Cd), B may be gallium (Ga), tin (Sn) or indium (In), and C may be zinc (Zn), cadmium (Cd), gallium (Ga), indium (In) or hafnium (Hf). In addition, X is not 0, and A, B and C are different from one another. In accordance with the present invention, the oxide semiconductor may be a material such as InZnO, InGaO, InSnO, ZnSnO, GaSnO, GaZnO, GaZnSnO, GaInZnO, ZnSnInO, HfInZnO, HfZnSnO and ZnO. This oxide semiconductor has an effective mobility, which is about 2 times to about 100 times that of the hydrogenated amorphous silicon.

A source electrode 173 and a drain electrode 175 may be formed on the semiconductor layer 154 to be spaced apart from each other. The source electrode 173 and the drain electrode 175 may partially overlap the gate electrode 124. The source electrode 173 may include first, second and third source electrodes 165s, 174s and 177s, and the drain electrode 175 may include first, second and third drain electrodes 165d, 174d and 177d.

A surface of each of the first source electrode 165s and the first drain electrode 165d may be in contact with the semiconductor layer 154, while the other surface thereof is in contact with the second source electrode 174s and the second drain electrode 174d, respectively. The first source electrode 165s and the first drain electrode 165d may be formed of the same material. For example, the first source electrode 165s and the first drain electrode 165d may include gallium zinc oxide (GaZnO), titanium (Ti), titanium alloy (such as TiN), molybdenum (Mo), copper, copper alloy (such as CuMn), or Cu-alloy nitride (such as CuMnN). The first source electrode 165s and the first drain electrode 165d may be formed to have a thickness of about 100 Å to about 600 Å. The first source electrode 165s and the first drain electrode 165d may serve to reduce the contact resistance between the semiconductor layer 154, and the second source electrode 174s and the second drain electrode 174d. If the semiconductor layer 154 is an oxide semiconductor layer including In, the first source electrode 165s and the first drain electrode 165d may suppress eduction (or extraction) of In due to reduction of In. The first source electrode 165s and the first drain electrode 165d may prevent atoms of the second source electrode 174s and the second drain electrode 174d from undergoing diffusion or electromigration into the semiconductor layer 154.

The second source electrode 174s and the second drain electrode 174d may be formed on the first source electrode 164s and the first drain electrode 164d, respectively. One surface of the second source electrode 174s may be in contact with the first source electrode 165s, while the other surface thereof may be in contact with the third source electrode 177s. One surface of the second drain electrode 174d is may be contact with the first drain electrode 165d, while the other surface thereof may be in contact with the third drain electrode 177d. The second source electrode 174s and the second drain electrode 174d may include copper or copper alloy. The copper alloy may include copper, and manganese (Mn), magnesium (Mg), aluminum (Al), zinc (Zn), or tin (Sn) of about 0.1 atomic % to about 30 atomic %. The second source electrode 174s and the second drain electrode 174d may be formed to have a thickness of about 1,000 Å to about 5,000 Å. The semiconductor layer 154 in an area existing between the second source electrode 174s and the second drain electrode 174d may form a channel.

The third source electrode 177s may be disposed on the second source electrode 174s, and the third drain electrode 177d may be disposed on the second drain electrode 174d. The third source electrode 177s and the third drain electrode 177d may be formed to have a thickness of about 100 Å to about 1,000 Å. The third source electrode 177s and the third drain electrode 177d may be formed of Cu-alloy nitride, CuMn alloy, CuMnAl alloy, or CuMn nitride (CuMnN). The Cu-alloy nitride may include vanadium (V), titanium (Ti), zirconium (Zr), tantalum (Ta), manganese (Mn), magnesium (Mg), chrome (Cr), molybdenum (Mo), cobalt (Co), niobium (Nb), or nickel (Ni). The third source electrode 177s and the third drain electrode 177d may prevent the second source electrode 174s and the second drain electrode 174d from being oxidized in a below-described process of forming a first protective film 181 or a second protective film 183.

A capping layer 179 may be formed on the tops and sidewalls of the source electrode 173 and the drain electrode 175 including copper. As shown in FIG. 2, the capping layer 179 may be formed on the tops and sidewalls of the third source and drain electrodes 177s and 177d, and on the sidewalls of the first and second source and drain electrodes 165s, 165d, 174s and 174d. If the first source and drain electrodes 165s and 165d include no copper but include some other materials, for example, gallium zinc oxide (GaZnO) or titanium alloy, the capping layer 179, unlike that shown in FIG. 2, may not be formed on the sidewalls of the first source and drain electrodes 165s and 165d. The capping layer 179 may prevent the source electrode 173 and the drain electrode 175 from forming a discolored layer by being discolored in the subsequent process, for example, in the etching process of a below-described protective film 180. In the absence of the capping layer 179, a discolored layer may be formed as atoms of a metal such as copper included in the source electrode 173 and the drain electrode 175 react with oxygen or sulfur, forming an oxide film or a sulfide film on the surfaces of the source electrode 173 and the drain electrode 175. The discolored layer may have a thickness of about 1 μm, and increases the surface roughness of the third source electrode 177s and the third drain electrode 177d, and when a blow-described pixel electrode 191 is formed, the discolored layer may cause disconnection of the pixel electrode 191. The disconnection of the pixel electrode 191 may significantly increase the contact resistance between the pixel electrode 191 and the third drain electrode 177d. The capping layer 179 may include cuprous oxide (CuO). The capping layer 179 may have a thickness of about 20 Å to about 100 Å. The film of cuprous oxide (CuO) may prevent the third source electrode 177s and the third drain electrode 177d from forming a discolored layer by further reacting to oxygen or sulfur during the subsequent process because it has a higher density compared to the discolored layer.

Although the source electrode 173 and the drain electrode 175 have a triple-layer structure in an embodiment of the present invention, the source electrode 173 and the drain electrode 175 may have a double-layer structure in another embodiment, in which the first source and drain electrodes 165s and 165d, or the third source and drain electrodes 177s and 177d are omitted.

The protective film 180 may be disposed on the sidewalls of the capping layer 179 and the semiconductor layer 154, and on the top of the gate insulating film 140. The protective film 180 may include the first protective film 181 and the second protective film 183. The first protective film 181 may be formed of silicon oxide (SiOx), and the second protective film 183 may be formed of silicon nitride (SiNx). The first protective film 181 including silicon oxide (SiOx) may prevent an oxide in the semiconductor layer 154 from being educed after being reduced. The second protective film 183 may planarize a lower film. The first protective film 181 and the second protective film 183 may have a thickness of about 300 Å to about 50,000 Å. The first protective film 181 and the second protective film 183 may be formed of an inorganic insulating material such as titanium oxide (TiO₂), alumina (Al₂O₃) or zirconia (ZrO₂), or an organic insulating material such as poly siloxane, phenyl siloxane, polyimide, silsesquioxane or silane. Any one of the first protective film 181 and the second protective film 183 may be omitted.

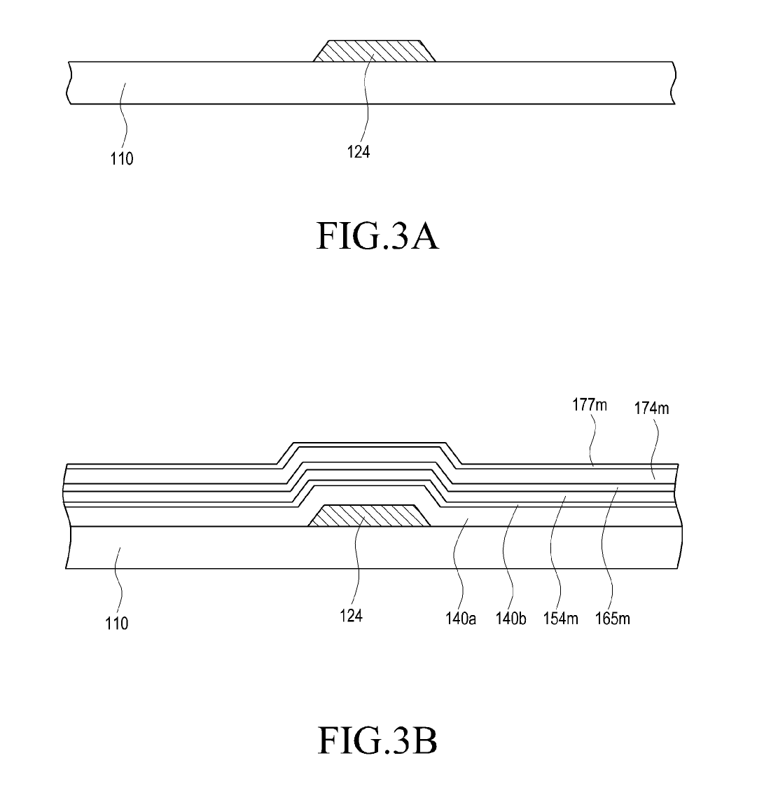

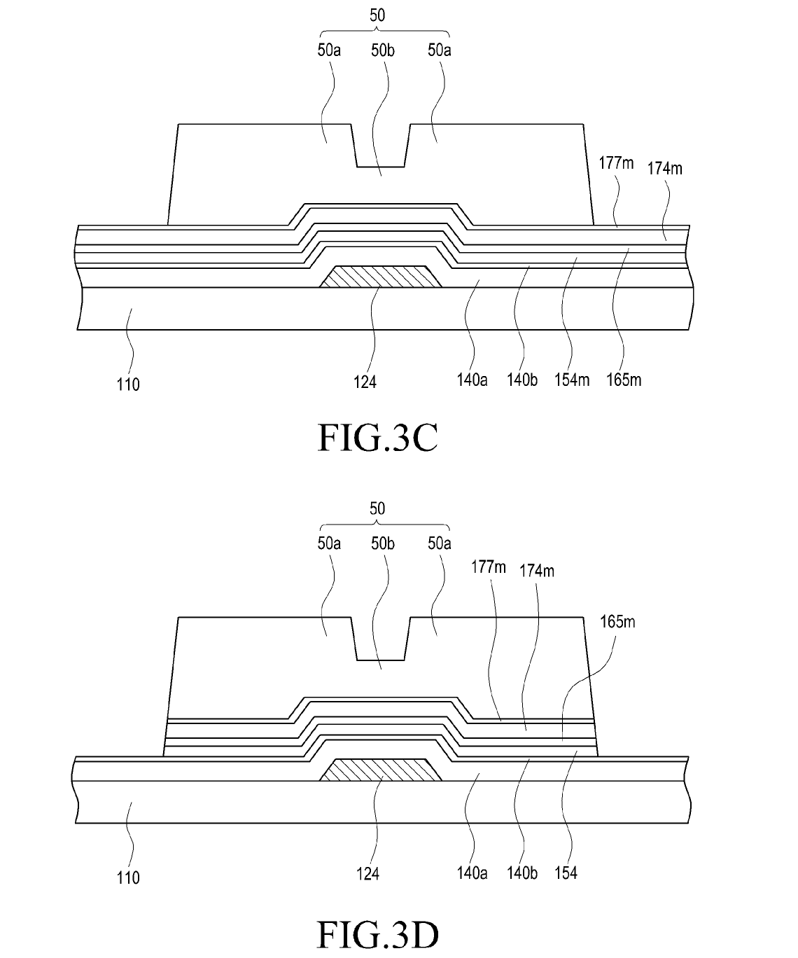

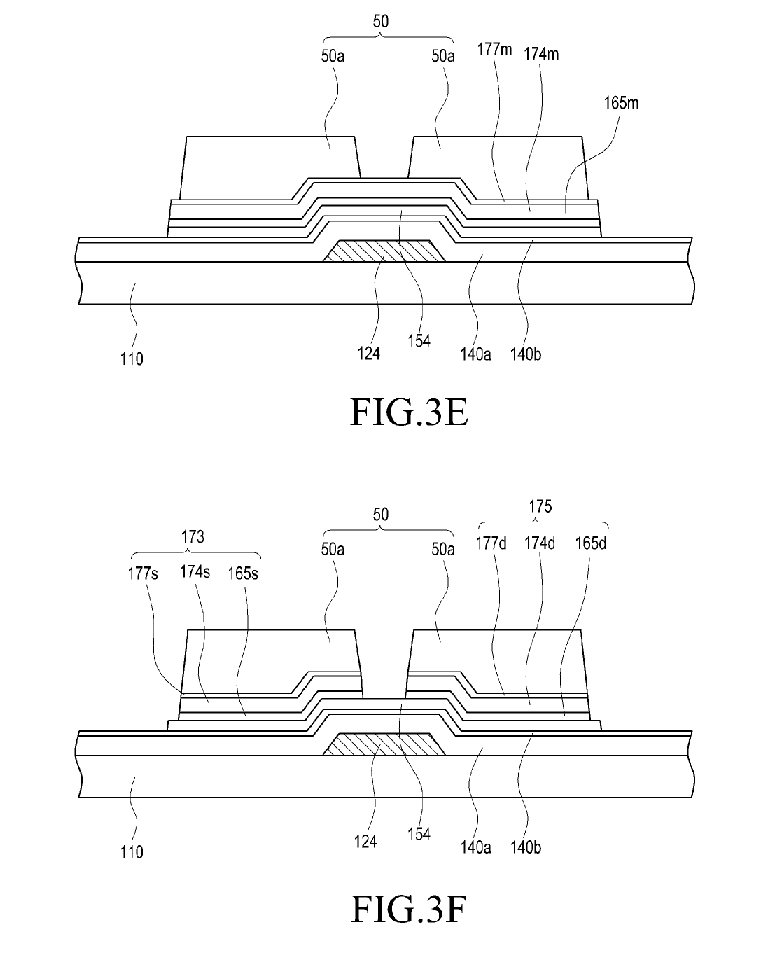

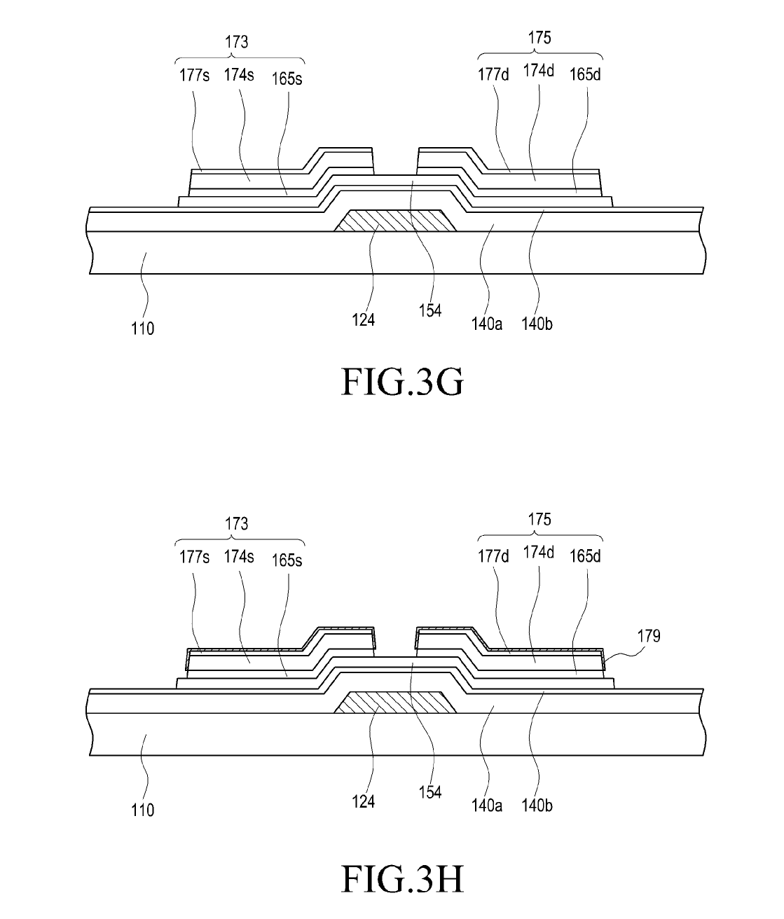

A method for manufacturing the TFT shown in FIG. 2 will be described in detail with reference to FIGS. 3A to 3H.

As shown in FIG. 3A, a gate conductive layer (not shown) may be formed on a substrate 110 by sputtering. The gate conductive layer (not shown) forms a gate electrode 124 through patterning using photolithography. The gate electrode 124 according to an embodiment of the present invention may have a double-layer structure including titanium and copper. The titanium layer may have a thickness of about 50 Å to about 1,000 Å, while the copper layer may have a thickness of about 1,000 Å to about 10,000 Å. The gate conductive layer having a double-layer structure of titanium and copper may be patterned by wet etching. An etchant used for the wet etching may include ammonium persulfate, aminotetrazole, nitric acid, acetic acid, methane citric acid and hydrofluoric acid (HF). In accordance with another embodiment, the gate conductive layer may be formed of the material described with reference to FIG. 2.

As shown in FIG. 3B, a first gate insulating film 140a and a second gate insulating film 140b may be formed on the gate electrode 124 and the substrate 110 by Chemical Vapor Deposition (CVD). The first gate insulating film 140a may be formed of silicon nitride (SiNx), and may have a thickness of about 1,000 Å to about 5,000 Å. The second gate insulating film 140b may be formed of silicon oxide (SiOx), and may have a thickness of about 300 Å to about 2,000 Å.

A first oxide layer 154m may be formed on the second gate insulating film 140b. The first oxide layer 154m may include indium gallium zinc oxide (InGaZnO). The first oxide layer 154m may be formed to have a thickness of about 200 Å to about 1,000 Å by sputtering. In accordance with another embodiment, the first oxide layer 154m may be formed of the material described with reference to FIG. 2.

A second oxide layer 165m may be formed on the first oxide layer 154m. The second oxide layer 165m may include gallium zinc oxide (GaZnO). The second oxide layer 165m may be formed to have a thickness of about 100 Å to about 600 Å by sputtering. In accordance with another embodiment, the second oxide layer 165m may be formed of the material described with reference to FIG. 2 and forming the first source electrode 165s and the first drain electrode 165d.

A first conductive layer 174m may be formed on the second oxide layer 165m. The first conductive layer 174m may be formed of copper by sputtering. The first conductive layer 174m may have a thickness of about 1,000 Å to about 5,000 Å.

A second conductive layer 177m may be formed on the first conductive layer 174m. The second conductive layer 177m may have a thickness of about 100 Å to about 1,000 Å. The second conductive layer 177m may be formed of CuMn alloy (e.g., CuMn or CuMnN) by sputtering. The CuMn alloy used for the second conductive layer 177m may form manganese oxide (MnOx) at the interface between the second conductive layer 177m and a protective film formed thereon. The manganese oxide (MnOx) may prevent the first conductive layer 174m from being oxidized during deposition of the protective film. The CuMn nitride (CuMnN) may be formed by performing plasma treatment on the surface of a Cu alloy with a nitrogen gas, or by annealing a Cu alloy in a nitrogen gas atmosphere.

In accordance with another embodiment, the second conductive layer 177m may be made of the material described with reference to FIG. 2 and forming the third source electrode 177s and the third drain electrode 177d.

A method for forming patterns of a semiconductor layer 154, a source electrode 173, and a drain electrode 175 will be described in detail with reference to FIGS. 3C to 3E.

As shown in FIG. 3C, a photoresist film 50 may be formed on the second conductive layer 177m. The photoresist film 50 may be patterned to form the source electrode 173 and the drain electrode 175. The patterned photoresist film 50 may have a thicker first portion 50a and a thinner second portion 50b. The thicker first portion 50a and the thinner second portion 50b may be formed by a mask (not shown) including slit patterns, grid patterns, or a semitransparent layer. The second portion 50b corresponds to a channel area of a TFT.

As shown in FIG. 3D, the first oxide layer 154m, the second oxide layer 165m, the first conductive layer 174m and the second conductive layer 177m, corresponding to the area where the photoresist film 50 is not formed, form the semiconductor layer 154 through removal by wet etching. The first oxide layer 154m formed of indium gallium zinc oxide (InGaZnO), the second oxide layer 165m formed of gallium zinc oxide (GaZnO), the first conductive layer 174m formed of copper, and the second conductive layer 177m formed of CuMn alloy may be etched by use of a first etchant. The first etchant may include persulfate, azole-including compounds, oxidation control agents, composition stabilizers, and oxidation supplements. The oxidation control agent may include nitric acid (HNO₃) which is inorganic acid, and acetic acid (AA) which is organic acid. The composition stabilizer may include at least one material such as methane citric acid, nitric acid, phosphoric acid, sulfuric acid, hydrochloric acid, and mixtures thereof. The oxidation supplement may include at least one material such as fluoride compound including fluorine (F) (e.g., hydrofluoric acid (HF)), ammonium fluoride (NH₄F), ammonium bifluoride (NH₄F₂), potassium fluoride (KF), sodium fluoride (NaF), calcium hydrogen fluoride (CaHF), sodium hydrogen fluoride (NaHF₂), ammonium fluoride (NH₄F), hydrogen ammonium fluoride (NH₄HF₂), ammonium fluoroborate (NH₄BF₄), potassium hydrogen fluoride (KHF₂), aluminum fluoride (AlF₃), fluoboric acid (HBF₄), lithium fluoride (LiF), potassium fluoroborate (KBF₄), calcium fluoride (CaF₂), fluosilicic acid, and mixtures thereof.

As shown in FIG. 3E, the second conductive layer 177m in an area corresponding to the channel may be exposed as the photoresist film 50 (50a and 50b) is removed by a predetermined thickness by known ashing. The predetermined thickness may be a thickness of the photoresist film 50b in the area where it overlaps the channel.

As shown in FIG. 3F, the source electrode 173, the drain electrode 175 and a channel area of the TFT may be formed as the second conductive layer 177m, the first conductive layer 174m and the second oxide layer 165m, which are not covered by the photoresist film 50 as shown in FIG. 3E, are removed. The second conductive layer 177m forms the third source electrode 177s and the third drain electrode 177d, the first conductive layer 174m forms the second source electrode 174s and the second drain electrode 174d, and the second oxide layer 165m forms the first source electrode 165s and the first drain electrode 165d. The removal of the second conductive layer 177m, the first conductive layer 174m, and the second oxide layer 165m may be achieved by using an etchant obtained by excluding the oxidation supplement from the first etchant described with reference to FIG. 3D.

As shown in FIG. 3G, the first portions 50a of the photoresist film 50, remaining on the tops of the third source electrode 177s and the third drain electrode 177d, may be removed. The semiconductor layer 154, the first source electrode 165s, the first drain electrode 165d, the second source electrode 174s, the second drain electrode 174d, the third source electrode 177s, and the third drain electrode 177d may be formed by the method described with reference to FIGS. 3B to 3F.

As shown in FIG. 3H, a capping layer 179 may be formed on the tops and sidewalls of the third source electrode 177s and the third drain electrode 177d, and on the sidewalls of the second source and drain electrodes 174s and 174d. The capping layer 179 may be formed by performing plasma treatment in an oxygen atmosphere. The plasma treatment may be performed at a pressure of about 30 mTorr to about 200 mTorr, and at a power density of about 0.8 W/cm² to about 1.6 W/cm². During the plasma treatment, oxygen may be used, and an inert gas such as argon or helium may be further used. The plasma treatment may be performed at room temperature for 10 seconds or more. In accordance with another embodiment, the plasma treatment may be performed at 150° C. or below. The capping layer 179 may include cuprous oxide (CuO). The forming of the capping layer 179 may prevent the source electrode 173 and the drain electrode 175 from being discolored, resulting in prevention of an increase in contact resistance. If the first source electrode 165s and the first drain electrode 165d include copper, the capping layer 179 may be formed on the sidewalls of the first source electrode 165s and the first drain electrode 165d, unlike that shown in FIG. 3H.

Thereafter, as shown in FIG. 2, a protective film 180 may be formed on the source electrode 173 and the drain electrode 175 by CVD. The protective film 180 may include a first protective film 181 and a second protective film 183. The first protective film 181 may be formed of silicon oxide (SiOx), and the second protective film 183 may be formed of silicon nitride (SiNx). In accordance with another embodiment, any one of the first protective film 181 and the second protective film 183 may be omitted.

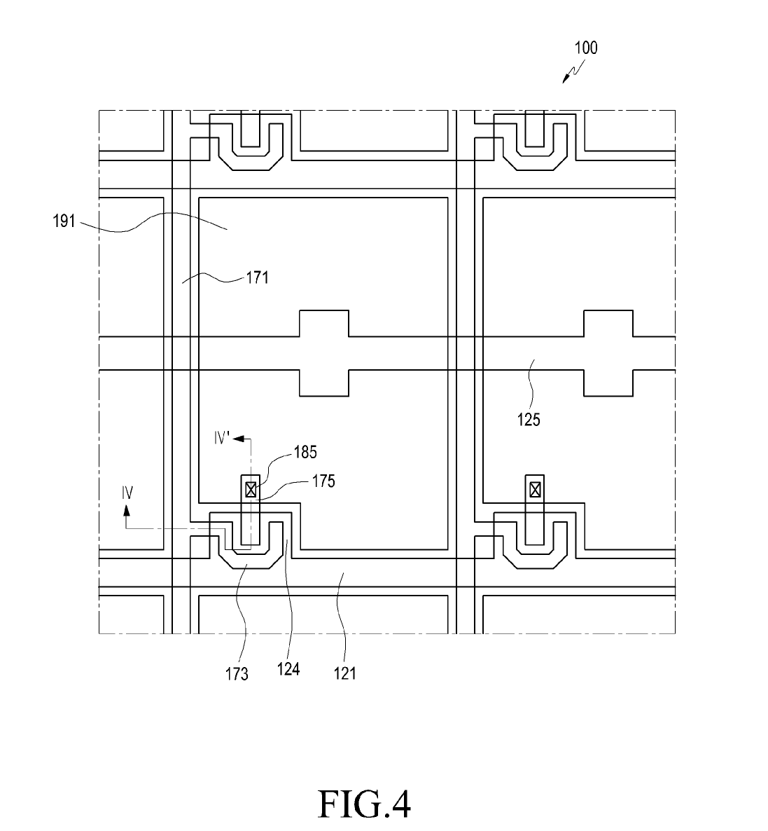

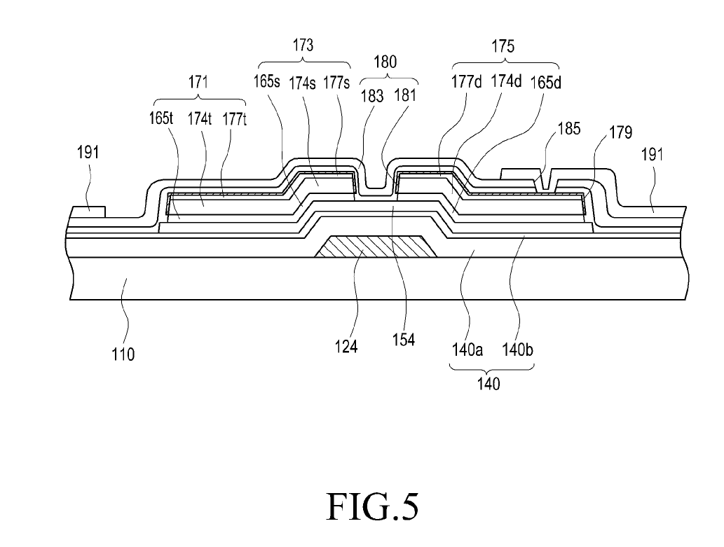

FIG. 4 is a layout of a TFT panel according to an embodiment of the present invention, and FIG. 5 is a cross-sectional view taken along the line IV-IV′ of the TFT panel shown in FIG. 4. A TFT panel 100 with the TFT in FIG. 2 will be described in detail below with reference to FIGS. 4 and 5.

Referring to FIGS. 4 and 5, a gate line 121 and a storage electrode line 125 may be disposed on a substrate 110. The substrate 110 may be made of a transparent material such as glass or plastic. The gate line 121 transfers gate signals, and extends in the horizontal or row direction. The gate line 121 has a gate electrode 124 projecting vertically, and on an end of the gate line 121 may be disposed a gate pad (not shown) for connection with a driving circuit (not shown) applying gate signals.

The storage electrode line 125 may form a storage capacitor by overlapping a portion of a below-described pixel electrode 191. The storage electrode line 125 may receive a constant voltage, and may extend in substantially parallel to the gate line 121. The gate line 121 and the storage electrode line 125 may be formed by the same method as the method for manufacturing a gate conductive layer, described with reference to FIG. 3A.

A gate insulating film 140 may be disposed on the gate line 121 and the storage electrode line 125. The gate insulating film 140 may include a first gate insulating film 140a and a second gate insulating film 140b. The first gate insulating film 140a may be in contact with the gate electrode 124, while the second gate insulating film 140b may be in contact with a below-described semiconductor layer 154. The first gate insulating film 140a may be formed of silicon nitride (SiNx), while the second gate insulating film 140b may be formed of silicon oxide (SiOx). The gate insulating film 140 may be formed by the method described above.

The semiconductor layer 154 may be disposed on the gate insulating film 140. The semiconductor layer 154 may be made of oxide semiconductor. The oxide semiconductor may be made of the material described above.

A data line 171, a source electrode 173, and a drain electrode 175 may be disposed on the semiconductor layer 154. The data line 171 transfers data signals, and extends vertically or perpendicularly. The source electrode 173 projects from the data line 171, and has a U-shape. The drain electrode 175 is spaced apart from the source electrode 173, facing the source electrode 173.

The data line 171 includes a first data line 165t, a second data line 174t disposed on the first data line 165t, and a third data line 177t disposed on the second data line 174t.

The source electrode 173 includes a first source electrode 165s, a second source electrode 174s disposed on the first source electrode 165s, and a third source electrode 177s disposed on the second source electrode 174s.

The drain electrode 175 includes a first drain electrode 165d, a second drain electrode 174d disposed on the first drain electrode 165d, and a third drain electrode 177d disposed on the second drain electrode 174d.

In accordance with an embodiment of the present invention, the first data line 165t, the first source electrode 165s, and the first drain electrode 165d may be made of gallium zinc oxide (GaZnO) or copper alloy. The second data line 174t, the second source electrode 174s, and the second drain electrode 174d may include copper or copper alloy. The third data line 177t, the third source electrode 177s, and the third drain electrode 177d may include CuMn alloy. In accordance with another embodiment, the data line 171, the source electrode 173 and the drain electrode 175 may be formed of the materials described above.

The semiconductor layer 154, the data line 171, the source electrode 173, and the drain electrode 175 may be formed by the method described above.

A capping layer 179 may be disposed on the tops and sidewalls of the data line 171, the source electrode 173 and the drain electrode 175, including copper. If the first data line 165t and the first source and drain electrodes 165s and 165d include no copper, the capping layer 179 may not be formed on the sidewalls of the first data line 165t and the first source and drain electrodes 165s and 165d, unlike that shown in FIG. 5. The capping layer 179 may be formed of cuprous oxide (CuO). The capping layer 179 may have a thickness of about 20 Å to about 100 Å. The capping layer 179 may be formed by the method described above.

A protective film 180 may be disposed on the sidewalls of the capping layer 179 and the semiconductor layer 154, and on the top of the gate insulating film 140. The protective film 180 may include a first protective film 181 and a second protective film 183. The first protective film 181 may be formed of silicon oxide (SiOx), while the second protective film 183 may be formed of silicon nitride (SiNx). The first protective film 181 including silicon oxide (SiOx) may prevent an oxide in the semiconductor layer 154 from being educed after being reduced. The second protective film 183 may planarize a lower film. The first protective film 181 and the second protective film 183 may be formed by CVD. Any one of the first protective film 181 and the second protective film 183 may be omitted.

A contact hone 185 may be formed in the protective film 180 to expose a portion of the drain electrode 175. The contact hole 185 may be formed by patterning the protective film 180 by a photolithography process in which a photoresist film is used. The protective film 180 may be patterned by dry etching. The dry etching may be performed using an SF₆ gas at a pressure of about 15 mTorr and at a power of about 1,000 W. The SF₆ used in the etching process of the protective film 180 or the sulfur (S) included in the photoresist film may form a metal sulfide film by reacting to the metal layer. The sulfur (S) may serve as a catalyst facilitating the oxidation of the metal layer. In the absence of the capping layer 179 according to an embodiment of the present invention, the data line 171, the source electrode 173 and the drain electrode 175 may be discolored by the sulfation or oxidation reaction. The discolored layer increasing contact resistances of the data line 171, the source electrode 173 and the drain electrode 175, may have a thickness of about 1 μm or more. In accordance with an embodiment of the present invention, the capping layer 179 may prevent the data line 171, the source electrode 173 and the drain electrode 175 from being discolored by reacting to the oxygen or sulfur in the etching process of the protective film 180, because it has a higher density compared to the discolored layer.

A pixel electrode 191 may be disposed on the protective film 180. The pixel electrode 191 may be electrically connected to the drain electrode 175 via the contact hole 185, and receives a data voltage from the drain electrode 175.

The pixel electrode 191, to which a data voltage is applied, may generate an electric field together with a common electrode (not shown) receiving a common voltage, and directions of liquid crystal molecules in a liquid crystal layer (not shown) disposed between these two electrodes are determined by this electric field. The liquid crystal layer disposed between the pixel electrode 191 and the common electrode forms a liquid crystal capacitor, and maintains the data voltage even after the TFT is turned off. The pixel electrode 191 may form a storage electrode by overlapping the storage electrode line 125, thereby making it possible to improve the voltage maintaining capability of the liquid crystal capacitor. The pixel electrode 191 may be formed of transparent conductor such as Indium-Tin-Oxide (ITO) or Indium-Zinc-Oxide (IZO).

Table 1 below shows occurrence of discoloration and contact resistance depending on oxygen plasma treatment conditions for forming the capping layer of the TFT panel illustrated in FIGS. 4 and 5. The contact resistance is a value measured in a Test Element Group (TEG) made of the same material as that of the drain electrode 175 and the pixel electrode 191. A 13.56 MHz RF plasma is used.

TABLE 1

| | | Experiment | Experiment | Experiment |
|---|---|---|---|---|
| | Example | 1 | 2 | 3 |
| Discoloration | ◯ | X | X | X |
| Contact | 9.59 × 10⁴ | 6.34 × 10³ | 7.97 × 10³ | 5.77 × 10³ |
| resistance (ohm) | | | | |

In Table 1, O represents occurrence of discoloration and X represents non-occurrence of discoloration.

A TFT panel in Example (representing a comparable example) is the same as the TFT panel described with reference to FIGS. 4 and 5 except that the plasma treatment was not performed in an oxygen atmosphere and the capping layer was not formed.

Experiment 1 represents an experiment (or an experimental example) in which oxygen plasma treatment was performed at a pressure of 30 mTorr and at a power density of 0.8 W/cm² for 60 seconds.

Experiment 2 represents an experiment in which oxygen plasma treatment was performed at a pressure of 200 mTorr and at a power density of 0.8 W/cm² for 60 seconds.

Experiment 3 represents an experiment in which oxygen plasma treatment was performed at a pressure of 30 mTorr and at a power density of 1.6 W/cm² for 60 seconds.

Discoloration was determined by a common optical microscope, and contact resistance was measured by equipment with a model number of HP4072. In Example, discoloration has occurred, and contact resistance in Example was higher than contact resistances in Experiments 1, 2 and 3. If contact resistance is less than or equal to about 1×10⁴ ohm, the contact resistance between the drain electrode 175 and the pixel electrode 191 is determined to have a high-quality level. Referring to Table 1, contact resistance in Example showed a low-quality level of 9.59×10⁴ ohm, whereas contact resistances in Experiments 1, 2 and 3 were improved to a high-quality level.

The manufactured TFT panel may prevent an increase in contact resistance between the drain electrode 175 and the pixel electrode 191, thus preventing the degradation in performance and picture quality of the TFT.

Although the TFT panel is used for, for example, a liquid crystal display device in an embodiment of the present invention, the TFT panel may be used as a switching device of another display device. For example, the TFT panel may be used as a switching device of a display device having Organic Light-Emitting Display (OLED), ElectroWetting Display (EWD), or Micro-ElectroMechanical System (MEMS).

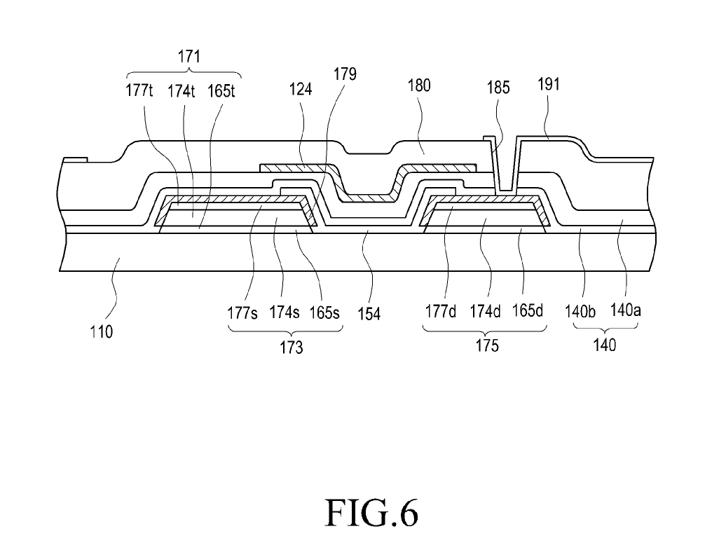

FIG. 6 is a cross-sectional view of a TFT panel according to another embodiment of the present invention. The TFT panel in FIG. 6 is substantially the same as the TFT panel shown in FIG. 4 except for the shapes and locations of the gate electrode 124 and the semiconductor layer 154.

Referring to FIGS. 4 and 6, a data line 171, a source electrode 173 and a drain electrode 175 may be disposed on a substrate 110. The substrate 110 may be a substrate of a transparent material such as glass or plastic. The data line 171 transfers data signals, and extends vertically or perpendicularly. The source electrode 173 projects from the data line 171, and has a U-shape. The drain electrode 175 is spaced apart from the source electrode 173, facing the source electrode 173. The substrate 110 is exposed between the source electrode 173 and the drain electrode 175.

The data line 171 may include a first data line 165t, a second data line 174t disposed on the first data line 165t, and a third data line 177t disposed on the second data line 174t.

The source electrode 173 may include a first source electrode 165s, a second source electrode 174s disposed on the first source electrode 165s, and a third source electrode 177s disposed on the second source electrode 174s.

The drain electrode 175 may include a first drain electrode 165d, a second drain electrode 174d disposed on the first drain electrode 165d, and a third drain electrode 177d disposed on the second drain electrode 174d.

The data line 171, the source electrode 173, and the drain electrode 175 may be formed by the method described above. In accordance with an embodiment of the present invention, the first data line 165t, the first source electrode 165s, and the first drain electrode 165d may be made of gallium zinc oxide (GaZnO) or copper alloy. The second data line 174t, the second source electrode 174s, and the second drain electrode 174d may include copper or copper alloy. The third data line 177t, the third source electrode 177s, and the third drain electrode 177d may include CuMn alloy. In accordance with another embodiment of the present invention, a protective film (not shown) may be further formed between the substrate 110, and the data line 171, the source electrode 173 and the drain electrode 175 to improve the interfacial properties between a semiconductor layer 154 and the substrate 110. The protective film may be made of a material such as silicon oxide (SiOx), silicon nitride (SiNx), and a mixture thereof.

In accordance with another embodiment of the present invention, a light-blocking layer (not shown) may be further formed the substrate 110, and the data line 171, the source electrode 173 and the drain electrode 175 to reduce a photocurrent on the semiconductor layer 154.

A capping layer 179 may be disposed on the tops and sidewalls of the data line 171, the source electrode 173 and the drain electrode 175, including copper. If the first data line 165t and the first source and drain electrodes 165s and 165d include no copper, the capping layer 179 may not be disposed on the sidewalls of the first data line 165t and the first source and drain electrodes 165s and 165d, unlike that shown in FIG. 6. The capping layer 179 may be formed of cuprous oxide (CuO). The capping layer 179 may have a thickness of about 20 Å to about 100 Å. The capping layer 179 may be formed by the method described above.

The semiconductor layer 154 may be disposed on the capping electrode 179 and the substrate 110 exposed between the source electrode 173 and the drain electrode 175. The semiconductor layer 154 may overlap the top surface of the capping layer 179, and may be disposed on sidewalls of the capping layer 179, which face each other. The semiconductor layer 154 may be made of oxide semiconductor. The oxide semiconductor may include indium gallium zinc oxide (InGaZnO) or indium zinc tin oxide (InZnSnO). The semiconductor layer 154 may be formed by the method described above.

A gate insulating film 140 may be disposed on the semiconductor layer 154, the capping layer 179, and the exposed substrate 110. The gate insulating film 140 may include a first gate insulating film 140a and a second gate insulating film 140b. The second gate insulating film 140b is in contact with the semiconductor layer 154, while the first gate insulating film 140a is in contact with a below-described gate electrode 124. The first gate insulating film 140a may be formed of silicon nitride (SiNx), while the second gate insulating film 140b may be formed of silicon oxide (SiOx). The gate insulating film 140 may be formed by the method described above.

A gate line 121 and a storage electrode line 125 may be disposed on the gate insulating film 140. The gate line 121 transfers gate signals, and extends in the horizontal or row direction. The gate line 121 has a gate electrode 124 projecting vertically, and on an end of the gate line 121 may be disposed a gate pad (not shown) for connection with a driving circuit (not shown) applying gate signals.

The storage electrode line 125 forms a storage capacitor by overlapping a portion of a below-described pixel electrode 191. The storage electrode line 125 receives a constant voltage, and extends in substantially parallel to the gate line 121. The gate line 121 and the storage electrode line 125 may be formed by the material and method described above.

A protective film 180 may be formed on the gate line 121, the storage electrode line 125, and the gate insulating film 140. The protective film 180 may include silicon nitride (SiNx). The protective film 180 may be formed by the method described above.

A contact hole 185 may be formed through the protective film 180 and the gate insulating film 140. The contact hole 185 exposes a portion of the drain electrode 175. The contact hole 185 may be formed by etching the protective film 180 and the gate insulating film 140 by the method described above. In the dry etching process of the protective film 180 and the gate insulating film 140, an SF₆ gas, or sulfur (S) or oxygen (O) included in a photoresist film may form a metal sulfide film or a metal oxide film by reacting to the metal layer. The sulfur (S) may serve as a catalyst facilitating the oxidation of the metal layer. In the absence of the capping layer 179 according to an embodiment of the present invention, the data line 171, the source electrode 173 and the drain electrode 175 may be discolored by the sulfation or oxidation reaction. The discolored layer may have a thickness of about 1 μm or more. The discolored layer may increase contact resistances of the data line 171, and the source electrode 173 and the drain electrode 175. In accordance with an embodiment of the present invention, the capping layer 179 may prevent the data line 171, the source electrode 173 and the drain electrode 175 from being discolored by reacting to the oxygen or sulfur in the etching process of the protective film 180, because it has a higher density compared to the discolored layer.

A pixel electrode 191 may be disposed on the protective film 180. The pixel electrode 191 is electrically connected to the drain electrode 175 via the contact hole 185, and receives a data voltage from the drain electrode 175.

The manufactured TFT panel 100 may prevent an increase in contact resistance between the drain electrode 175 and the pixel electrode 191, thus preventing the degradation in performance and picture quality of the TFT.

As is apparent from the foregoing description, according to exemplary embodiments of the present invention, an increase in contact resistance of low-resistance conductive lines may be prevented, making it possible to prevent the degradation in performance of a TFT with the low-resistance conductive lines. Other effects of the present invention may be derived from the detailed foregoing description.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A Thin Film Transistor (TFT) panel comprising:
a substrate;
a source electrode and a drain electrode disposed on the substrate and spaced apart from each other;
a capping layer disposed on top surfaces and sidewalls of the source electrode and the drain electrode;
a protective film disposed on the source electrode and the drain electrode;
a contact hole formed in the protective film and exposing the capping layer; and
a pixel electrode electrically connected to the exposed portion of the capping layer via the contact hole.

2. The TFT panel of claim 1, wherein each of the source electrode and the drain electrode comprises a first layer, a second layer comprising copper, and a third layer comprising copper alloy, and the capping layer is disposed on a top and a sidewall of the third layer and on a sidewall of the second layer.

3. The TFT panel of claim 2, wherein the capping layer comprises cuprous oxide (CuO).

4. The TFT panel of claim 3, wherein the capping layer has a thickness of about 20 Å to about 100 Å.

5. The TFT panel of claim 1, wherein the capping layer comprises cuprous oxide (CuO).

6. The TFT panel of claim 5, wherein the capping layer has a thickness of about 20 Å to about 100 Å.

7. A method for manufacturing a Thin Film Transistor (TFT) panel, comprising:
forming a source electrode and a drain electrode on a substrate;
forming a capping layer by performing plasma treatment on the source and drain electrodes in an oxygen atmosphere;
forming a protective film on the source electrode, the drain electrode, and the capping layer;
forming a contact hole in the protective film to expose the capping layer; and
forming a pixel electrode electrically connected to the capping layer via the contact hole.

8. The method of claim 7, wherein the plasma treatment is performed at a pressure of about 30 mTorr to about 200 mTorr.

9. The method of claim 8, wherein the plasma treatment is performed at a power density of about 0.8 W/cm² to about 1.6 W/cm².

10. The method of claim 9, wherein the plasma treatment is performed for about 10 seconds or more.

11. The method of claim 7, wherein the plasma treatment is performed at a power density of about 0.8 W/cm² to about 1.6 W/cm².

12. An electronic device comprising:
a substrate;
a lower conductive layer disposed on the substrate and comprising copper;
a capping layer disposed on a top and a sidewall of the lower conductive layer;
an interlayer insulating film disposed on the capping layer;
a contact hole formed in the interlayer insulating film; and
an upper conductive layer electrically connected to the capping layer via the contact hole.

13. The electronic device of claim 12, wherein the capping layer comprises cuprous oxide (CuO).

14. The electronic device of claim 13, wherein the capping layer has a thickness of about 20 Å to about 100 Å.

15. A Thin Film Transistor (TFT) comprising:
a substrate;
a gate electrode, a source electrode and a drain electrode disposed on the substrate;
an oxide semiconductor layer interposed between the gate electrode and the source and drain electrodes, wherein at least one of the source and drain electrodes comprises copper;
a capping layer disposed on a top and a sidewall of any one of the source and drain electrodes, which comprises copper; and
a protective film disposed on the capping layer.

16. The TFT of claim 15, wherein the source and drain electrodes comprise first, second and third source electrodes, and first, second and third drain electrodes, respectively, and the capping layer is disposed on top surfaces of the third source electrode and the third drain electrode, and on sidewalls of the second source electrode and the second drain electrode.

17. The TFT of claim 16, wherein the capping layer comprises cuprous oxide (CuO).

18. The TFT of claim 17, wherein the capping layer has a thickness of about 20 Å to about 100 Å.
